(19) United States
(12) Patent Application Publication
(10) Pub. No.: US 2011/0209902 A1
(43) Pub. Date: Sep. 1, 2011

(54) CURRENT COLLECTOR SYSTEMS FOR USE IN FLEXIBLE PHOTO ELECTRICAL AND DISPLAY DEVICES AND METHODS OF FABRICATION

(75) Inventors: Gavin Tulloch, New South Wales (AU); Johann Desilvestro, New South Wales (AU); Damion Milliken, New South Wales (AU)

(73) Assignee: DYESOL LTD., New South Wales (AU)

(21) Appl. No.: 13/058,654

(22) PCT Filed: Aug. 12, 2009
(86) PCT No.: PCT/AU09/01036

§ 371 Date: May 18, 2011

(30) Foreign Application Priority Data
Aug. 12, 2008 (AU) 2008 904 122

(51) Int. Cl. H05K 1/02; H05K 3/20; H05K 3/00

(52) U.S. Cl. 174/254; 29/831; 156/60

(57) ABSTRACT

A conductor assembly for use in fabricating a photoelectrical device is disclosed including: a number of electrically conductive filaments; a number of substantially transparent filaments; and wherein the conductive and transparent filaments are joined together to form a flexible web. Photoelectrical devices or sub-assemblies fabricated to include the conductor assembly are also disclosed.

### TECHNICAL FIELD

This invention relates to substantially transparent current collector systems for use in photoelectrical devices including display devices. Such devices may include, but are not limited to, photovoltaic devices such as solar cells, or photocatalytic devices such as those utilised for splitting water into hydrogen and oxygen, or electrochromic windows or displays, or LCD or OLED (organic light emitting diode) displays.

### BACKGROUND TO THE INVENTION

The two properties of electrical conductivity and optical transparency in the UV-Vis-IR wavelength range are both required for at least one electrode in any photoelectrical device such as a solar cell, or more specifically a dye-sensitised solar cell. Ideally high conductivity (e.g., silver) should be combined with high transmissivity (e.g. >95%). However, almost all practical transparent conducting materials exhibit an inverse relationship between these two essential parameters, and a compromise must be reached between the two criteria for any specific application. Designs for such photoelectrical devices typically favour lower conductivities so as to achieve higher optical transmissivities, and ensure that appropriate high conductivity current collection pathways (“fingers”) are spaced closely enough together so as to minimise voltage losses through the lower conductivity transparent conductor.

There is a continued need to provide alternative or improved conductor arrangements and fabrication techniques for photoelectrical devices.

### SUMMARY OF THE INVENTION

In a first aspect the present invention provides a conductor assembly for use in fabricating a photoelectrical device including: a number of electrically conductive filaments; a number of substantially transparent filaments; and wherein the conductive and transparent filaments are joined together to form a flexible web.

In large scale manufacture of photoelectrical devices, such a conductor assembly may be fabricated on a dedicated production line and be delivered to a subsequent stage of manufacture in the form of a roll, for instance, to facilitate roll-to-roll processing. The transparent filaments serve to retain the structure of the conductor assembly during subsequent processes. When fabricated into a photoelectrochemical device, the transparent filaments do not block light from entering the cell, thus maximising captured light and cell performance.

The web may be in the form of a mesh.

The conductive filaments may be aligned predominantly in a first direction; and the transparent filaments may be aligned predominantly in a second direction.

The first direction and the second direction may be substantially orthogonal to one another.

The conductors may be formed from a material including any of copper, Ti, steel, stainless steel; Sn, Pt, Pb, Fe, manganin, constantan, Ag, Au, Al, W, Ni, Mo, and alloys thereof including brass.

The substantially transparent filaments may be formed from a polymer such as polyesters including polyethylene terephthalates or polyethylene naphthalates, polyamides, polyolefines including polypropylenes, polyetherketones, polyetheretherketones polyarylsulfones, polyethersulfones, polyphenylene sulfones, polyvinyl chlorides, or fluorinated polymers.

In a second aspect the present invention provides a sub-assembly for use in fabricating a photoelectrical device including: a flexible, substantially transparent substrate; a conductor assembly according to the first aspect of the invention; and a layer of transparent electrically conductive material associated with the substrate and the conductor assembly.

The conductors may be at least partially embedded in the substrate.

The conductors may be affixed to the substrate with adhesive.

The conductors may be part of an anisotropic mesh.

The conductors of the conductor assembly may be disposed between the transparent electrically conductive material and the substrate.

The transparent electrically conductive material may include any of carbon nanotubes, ITO, FTO, doped or modified tin oxide or zinc oxide, poly(3,4-ethylenedioxythiophene) (PEDOT), poly(3,4-ethylenedioxythiophene) poly(styrenesulfonate) (PEDOT:PSS), poly(3,4-ethylenedioxythiophene)-tetramethacrylate (PEDOT:TMA), polyaniline or polypyrrole.

In a third aspect the present invention provides a method of fabricating a sub-assembly for use in fabricating a photoelectrical device including the steps of: providing a conductor assembly according to the first aspect of the invention; providing a flexible and substantially transparent substrate; and associating the conductor assembly with the substrate.

The step of associating the conductor assembly with the substrate may include the step of at least partially embedding the conductor assembly in the flexible substrate.

The step of embedding the conductor assembly may involve heat treatment.

The step of associating the conductor assembly with the substrate may involve use of an adhesive.

The conductor assembly may be unwound from a roll and the sub-assembly formed in a continuous roll process.

The method may further include the step of associating a layer of transparent electrically conductive material with the substrate.

The transparent electrically conductive material may be applied by a printing or spraying process.

In a fourth aspect the present invention provides a flexible photoelectrical device fabricated using a sub-assembly according to the third aspect of the invention.

### BRIEF DESCRIPTION OF THE DRAWINGS

Embodiments of the present invention will now be described, by way of example only, with reference to the accompanying drawings, in which:

FIG. 1 is a cross sectional view of a sub-assembly according to an embodiment of the invention for use in fabricating a photoelectrical device;

FIG. 2 is a top view of the sub-assembly of FIG. 1;

FIGS. 3A to 3H are cross sectional views of sub-assemblies according to other embodiments of the invention; and

FIG. 4 is a schemtic illustration of a conductor assembly according to an embodiment of the invention.

### DETAILED DESCRIPTION OF THE INVENTION

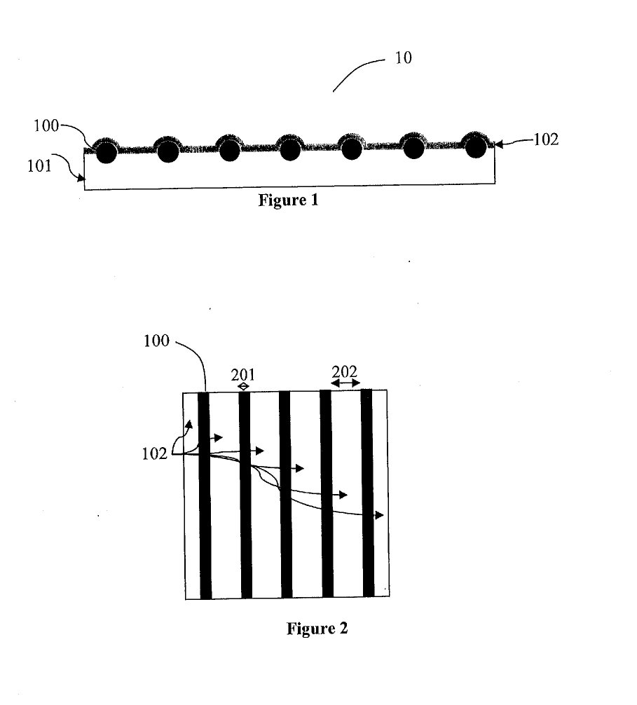

Referring to FIG. 1, a sub-assembly 10 for use in fabricating photoelectrical devices is shown including a flexible, transparent substrate 101 formed from a polymer film such polyethylene terephtalate (PET), a number of flexible conductors in the form of titanium filaments 100 and a layer of transparent electrically conductive material 102 such as a very thin film of carbon nanotubes.

FIG. 2 depicts a plan view of the sub assembly of FIG. 1 and highlights some important dimensions. The conductors 100 (herein now called “fingers”) have a “finger” width W (201) and inter-“finger” spacing S (202). The high transmissivity conductive layer 102 is disposed between the “fingers” (100). The transparent current collector is further characterised by two parameters of the high transmissivity conductor disposed between the “fingers”: transmissivity of the high transmissivity conductor (T) and sheet resistance of the high transmissivity conductor (γ). The transparent current collector is still further characterised by two parameters of the “fingers” themselves: cross sectional area of each “finger” (A) and resistivity of the “finger” material (ρ).

The sub-assembly 10 is fabricated in a continuous roll-to roll process. The substrate 101 sheet material is unwound from a roll. As this occurs, a number of copper filaments are unwound from reels to be applied to the substrate in parallel to one another at predetermined spacings. Heat and pressure is applied to the copper filaments to cause some localised melting of the substrate material. The conductors become partially embedded in the substrate which provides a degree of mechanical strength. Thereafter, the layer of transparent material is applied by a printing process.

In this embodiment, the conductors are formed from copper. In other embodiments, different materials can be used. The “finger” materials should be selected from materials having a resistivity p of preferably <500 nΩm (e.g., Ti, and various alloys such as stainless steel); more preferably <200 nΩm (e.g., Sn, Pt, Pb, Fe, and various alloys such as Manganin and Constantan); and most preferably <100 nΩm (e.g., Ag, Cu, Au, Al, W, Ni, Mo, and various alloys such as Brass). Lower resistivity materials result in more efficient devices due to reduced losses during electron transport via the “fingers”. Care must also be taken to select materials of suitable chemical compatibility to other components of the system.

The “finger” materials should be dimensioned such that their cross sectional area A is: preferably 25 μm²<A<25,000 μm²; more preferably 500 μm²<A<10,000 μm²; and most preferably 1,000 μm²<A<5,000 μm². “Fingers” of too small a cross sectional area are very fine and difficult to utilise during manufacture, and more costly to produce. “Fingers” of too large a cross sectional area render the overall device thickness too large, resulting in less efficient devices. Note that although the highly conductive elements (100 in FIG. 1) are shown with a circular cross section, the form of these elements need not be limited to only cylindrical in shape and may include, for instance, elliptical, square, rectangular, or any other cross sectional profile.

The high transmissivity conductor sheet 102 resistance γ should be selected such that: preferably 5 Ohm/square<γ<10,000 Ohm/square; more preferably 100 Ohm/square <γ<5,000 Ohm/square; and most preferably 250 Ohm/square <γ<1,000 Ohm/square. Transparent conductors with low sheet resistances have either high material or manufacturing costs, or low transmissivities. Too high a transparent conductor sheet resistance value, however, reduces device performance due to resistive losses transporting electrons to or from “fingers”.

The high transmissivity conductor transmissivity T should be selected such that: preferably T>80%; more preferably T>85%; and most preferably T>90%. Higher transmissivity transparent conductors improve device efficiency as they allow greater amounts of light through. Care must be taken to ensure chemical compatibility between the transparent conductor and other device constituents.

In this embodiment, the high transmissivity conductor material is based on a thin film of carbon nanotubes. In other embodiments suitable high transmissivity conductor materials include, for example, appropriately dimensioned granular layers of: ITO, FTO, otherwise doped or modified tin oxide or zinc oxide, poly(3,4-ethylenedioxythiophene) (PEDOT), poly(3,4-ethylenedioxythiophene) poly(styrenesulfonate) (PEDOT:PSS), poly(3,4-ethylenedioxythiophene)-tetramethacrylate (PEDOT:TMA), polyaniline or polypyrrole. Non-dense nanowire, nanofibre, or nanotube arrays of appropriate materials may also fulfil the role of a high transmissivity conductor, using, for example: PEDOT, PEDOT:PSS, PEDOT:TMA or carbon.

The “fingers” should be spaced S apart such that: preferably 0.05 mm<S<10 mm; more preferably 0.25 mm<S<5 mm; and most preferably 0.5 mm<S<2 mm. Too close a spacing of “fingers” reduces the performance of a device by blocking too much incident light, as well as presenting cost and manufacturing issues. Too distant a spacing of “fingers” reduces the performance of a device by increasing resistive losses during electron transmission to or from the “fingers”.

The “fingers” may be incorporated into a device by a number of different techniques. For example, “fingers” may be patterned onto an appropriate substrate using a suitably formulated conductive ink in combination with any commonly employed roll-to-roll or web adaptable printing technique, including, but not limited to: rotary screen printing, gravure printing or flexographic printing.

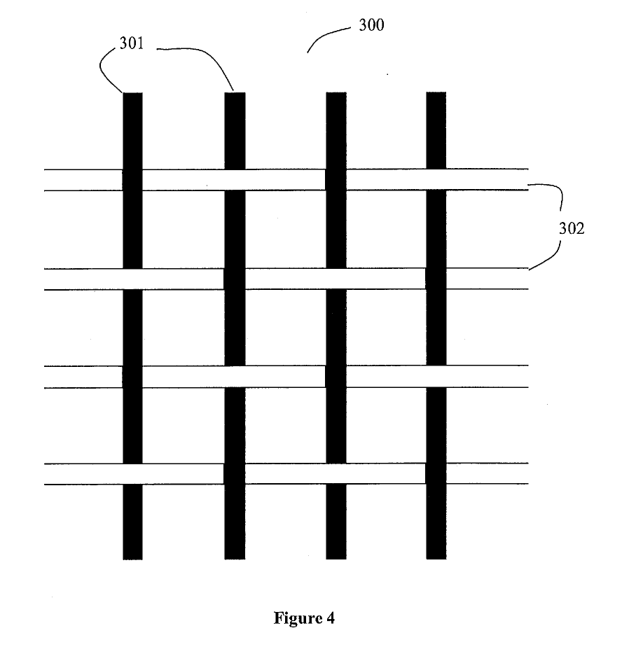

Referring to FIG. 4, the conductive “fingers” may be provided in the form of a conductor assembly which is in the form of a web such as an anisotropic woven mesh 300, in which conductive filaments 301 are aligned in the desired conduction direction. Transparent filaments 302 are aligned orthogonally to the conductive filaments 301 and are formed from a highly transparent but non-conductive material. Suitable materials include polymers such as polyesters including polyethylene terephthalates or polyethylene naphthalates, polyamides, polyolefines including polypropylenes, polyetherketones, polyetheretherketones polyarylsulfones, polyethersulfones, polyphenylene sulfones, polyvinyl chlorides, fluorinated polymers, or any polymer or copolymer providing the desired mechanical and optical properties as well as sufficient chemical resistance to any solution the device is in contact with.

The mesh 300 of FIG. 4 conducts electrical current uni-directionally in the direction of the conductive filaments 301. However, such an anisotropic mesh need not have conductive/opaque and non-conductive/transparent filaments of the same spacing or cross section, or have a 1:1 mesh weave, or have every filament in the desired conduction direction be the conductive/opaque material. A roll of such an anisotropic mesh may be unwound and bonded to an unwinding roll of substrate via roller, if required with elevated temperature, to form any required embedding and to bond the anisotropic mesh to the substrate.

A mesh may be woven or layered, and may be connected at the nodes by a heat process and/or adhesive. The mesh may be flattened after weaving such as by passing the mesh through a pair of calandering rollers, which optionally are heated, in order to partially embed the metal wires into the polymer strands at the metal-polymer intersection nodes.

The mesh may be partially embedded into the substrate. Depending on the relative melting points of the polymer fibres and the substrate (or the top layer if the substrate is a laminate), different situations will arise. If the melting or softening point of the polymer fibres is substantially higher than the melting or softening point of the substrate (or the top layer if the substrate is a laminate) the polymer fibres will, along with the metal fibres, be partially embedded into the substrate (or into the top layer if the substrate is a laminate) without being distorted substantially. If, on the other hand, the melting or softening point of the polymer fibres is substantially lower than the melting or softening point of the substrate (or the top layer if the substrate is a laminate) only the metal fibres will be embedded substantially into the substrate (or into the top layer if the substrate is a laminate) and the polymer fibres will fully or partially melt and be distorted substantially without getting embedded to a substantial degree into the substrate (or into the top layer if the substrate is a laminate). In a preferred embodiment of the present invention the melting or softening point of the polymer fibres is substantially higher than the melting or softening point of the substrate (or the top layer if the substrate is a laminate)

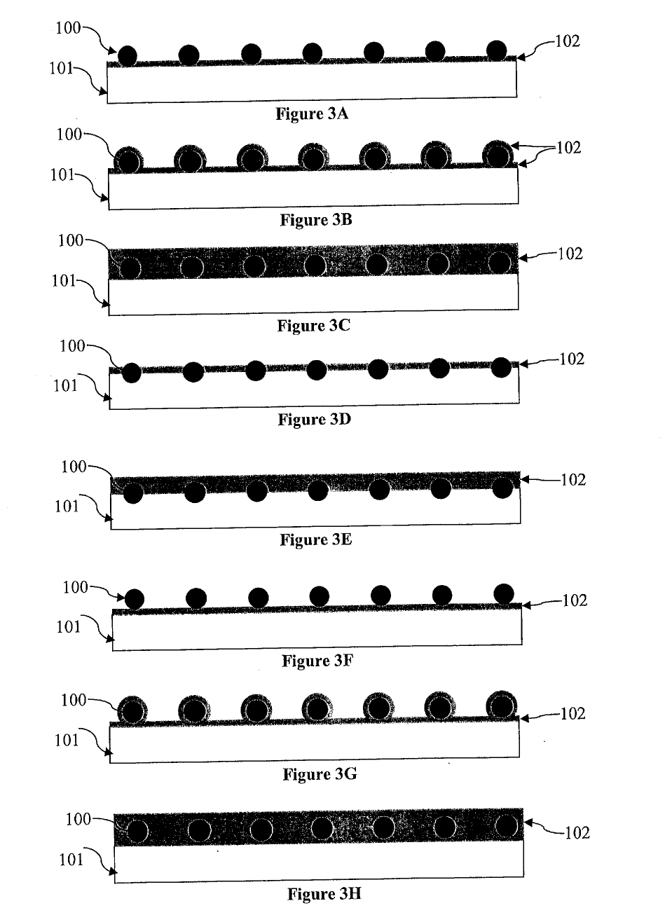

Referring to FIGS. 3A to 3H, in other embodiments the high transmissivity conductive material may be applied in other ways: directly to the substrate prior to “finger” patterning/deposition/embedding/bonding/etc.; in the case of suitably freestanding and pre-spaced “fingers” such as an anisotropic mesh, between the “fingers” prior to embedding and/or bonding the “fingers” to the substrate, either only between the “fingers”, both between and over one side of the “fingers”, or encasing the “fingers”, or otherwise; over the “fingers” after patterning/deposition/embedding/bonding/etc., either only between the “fingers”, or both between and over the top of the “fingers”, or encasing the exposed portions of the “fingers”, or otherwise; or any combination of the above.

In the embodiment in which the presently disclosed transparent anisotropically conductive current collectors are employed in a dye sensitised solar cell (DSC), they may be used on either the anode, cathode, or both sides of the device.

When used on the anode, the so called “working electrode” (WE), side of the device, in which electrons are liberated from photoexcited sensitising constituents into a mesoporous nanostructured scaffolding, the mesoporous nanostructured scaffolding may require appropriate low temperature processing so as to be compatible with the selected transparent anisotropically conductive current collector and substrate materials. Such low temperature processing can be achieved, for example, by utilising appropriately nanosized high band gap semiconductor oxides (e.g., TiO₂, ZnO, Nb₂O₅, etc.) dispersed in a suitably low temperature processable medium with low temperature activated interlinking agents. Such materials and processes are known in the prior art.

When used on the cathode, the so called “counter electrode” (CE), side of the device, in which electrons are returned to the device from an external circuit and recombine with oxidised redox species from the electrolyte via an electrocatalytic agent, the electrocatalytic agent may require appropriate low temperature processing so as to be compatible with the selected transparent anisotropically conductive current collector and substrate materials. Such low temperature processing can be achieved, for example, by coating the transparent anisotropically conductive current collector in a film of appropriate electrocatalytic agent chemical precursor(s), for example by spraying, roller coating, immersion, dip coating, or drop coating, etc., combined with appropriate low temperature processing of theses precursors to yield the desired shape and morphology of the electrocatalytic agent. An example is chemical reduction of hexachloroplatinic acid by a suitable reducing agent such as sodium borohydride at low temperature to form nano-platinum cluster electrocatalytic agents. Electrocatalytic agents may also be deposited, for example, by PVD such as sputter coating of platinum, PEDOT, PEDOT:PSS, PEDOT:TMA, or cabon. Further, electrocatalytic agents may be coated or otherwise deposited, for example, by doctor blading, drop coating, spin coating etc. of a suitable dispersed formulation of PEDOT, PEDOT:PSS, PEDOT:TMA, carbon, or platinum.

In some embodiments, the mesh itself may also function as a substrate.

In some embodiments utilising a mesh, the mesh is not associated with a transparent electriclly conductive layer.

This disclosure utilises the example of a dye-sensitised solar cell as the photoelectrical device, but the field of application for this invention is much wider, and the use of this specific example is not to be taken as indicating that the invention is only applicable to dye-sensitised solar cells. Embodiments of the invention may have application in thin film technologies, CdTe, CIS/CIGS, α-Si; silicon-based technologies; and organic PV.

Note that although the highly conductive elements (100) have been shown with a circular cross section, the form of these elements need not be limited to only cylindrical in shape and may include, for instance, elliptical, square, rectangular, or any other cross sectional profile.

1-20. (canceled)

21. A sub-assembly for use in fabricating a photoelectrical device, the sub-assembly comprising:
a flexible, substantially transparent substrate;
a conductor assembly, and the conductor assembly including a number of electrically conductive filaments;
a number of substantially transparent filaments; and
the conductive and transparent filaments being joined together to form a flexible web;
wherein the web is anisotropic; and
a layer of transparent electrically conductive material is associated with the substrate and the conductor assembly.

22. The sub-assembly according to claim 21, wherein the conductors are at least partially embedded in the substrate.

23. The sub-assembly according to claim 21, wherein the conductors are affixed to the substrate by an adhesive.

24. The sub-assembly according to claim 21, wherein the conductors are part of an anisotropic mesh.

25. The sub-assembly according to claim 21, wherein the conductors of the conductor assembly are disposed between the transparent electrically conductive material and the substrate.

26. The sub-assembly according to claim 21, wherein the transparent electrically conductive material includes any of carbon nanotubes, ITO, FTO, doped or modified tin oxide or zinc oxide, poly(3,4-ethylenedioxythiophene) (PEDOT), poly(3,4-ethylenedioxythiophene) poly(styrenesulfonate) (PEDOT:PSS), poly(3,4-ethylenedioxythiophene)-tetramethacrylate (PEDOT:TMA), polyaniline or polypyrrole.

27. The sub-assembly according to claim 21, wherein the web is a mesh.

28. The sub-assembly according to claim 21, wherein the conductive filaments are aligned predominantly in a first direction; and
the transparent filaments are aligned predominantly in a second direction.

29. The sub-assembly according to claim 28, wherein the first direction and the second direction are substantially orthogonal to one another.

30. The sub-assembly according to claim 21, wherein the conductors are formed from a material including at least one of copper, Ti, steel, stainless steel; Sn, Pt, Pb, Fe, manganin, constantan, Ag, Au, Al, W, Ni, Mo, and alloys thereof including brass.

31. The sub-assembly according to claim 21, wherein the substantially transparent filaments are formed from a polymer such as polyesters, including polyethylene terephthalates or polyethylene naphthalates, polyamides, polyolefines including polypropylenes, polyetherketones, polyetheretherketones polyarylsulfones, polyethersulfones, polyphenylene sulfones, polyvinyl chlorides, or fluorinated polymers.

32. A method of fabricating a sub-assembly for use in fabricating a photoelectrical device, the method comprising the steps of:
providing a conductor assembly, with the conductor assembly including: a number of electrically conductive filaments; a number of substantially transparent filaments; the conductive and transparent filaments are joined together to form a flexible web; and wherein the web is anisotropic;
providing a flexible and substantially transparent substrate; and
associating the conductor assembly with the substrate.

33. The method according to claim 32, wherein the step of associating the conductor assembly with the substrate further comprising the step of at least partially embedding the conductor assembly in the flexible substrate.

34. The method according to claim 33, wherein the step of embedding the conductor assembly further comprising the step of using heat treatment.

35. The method according to claim 32, wherein the step of associating the conductor assembly with the substrate further comprising the step of using an adhesive.

36. The method according to claim 32 further comprising the steps of unwinding the conductor assembly from a roll and forming the sub-assembly during a continuous roll process.

37. The method according to any one of claim 33, further comprising the step of associating a layer of transparent electrically conductive material with the substrate.

38. The method according to claim 37, further comprising the step of applying the transparent electrically conductive material by one of a printing or spraying process.

39. The method according to claim 32, further comprising the step of using a mesh as the web.

40. The method according to claim 32, further comprising the step of aligning the conductive filaments in a first direction; and
aligning the transparent filaments in a second direction.

41. The method according to claims 40, further comprising the step of arranging the first direction to be substantially orthogonal to the second direction.

42. The method according to claim 32, further comprising the step of forming the conductors from a material including at least one of copper, Ti, steel, stainless steel; Sn, Pt, Pb, Fe, manganin, constantan, Ag, Au, Al, W, Ni, Mo, and alloys thereof including brass.

43. The method according to claim 32, further comprising the step of forming the substantially transparent filaments from a polymer such as polyester, including polyethylene terephthalates or polyethylene naphthalates, polyamides, polyolefines including polypropylenes, polyetherketones, polyetheretherketones polyarylsulfones, polyethersulfones, polyphenylene sulfones, polyvinyl chlorides, or fluorinated polymers.

44. A flexible photoelectrical device fabricated from a sub-assembly, the sub-assembly comprising:
a flexible, substantially transparent substrate;
a conductor assembly, and the conductor assembly including a number of electrically conductive filaments;
a number of substantially transparent filaments; and
the conductive and transparent filaments being joined together to form a flexible web;
wherein the web is anisotropic; and
a layer of transparent electrically conductive material is associated with the substrate and the conductor assembly.
